(19) United States
(12) Patent Application Publication
(10) Pub. No.: US 2008/0094054 A1
(43) Pub. Date: Apr. 24, 2008

(54) Fuel Cell State Monitor Apparatus and Method

(76) Inventor: Makoto Takeyama, Aichi (JP)

Correspondence Address: KENYON & KENYON LLP, 1500 K STREET N.W., SUITE 700, WASHINGTON, DC, 20005, US

(21) Appl. No.: 11/792,781

(22) PCT Filed: Feb. 28, 2006
(86) PCT No.: PCT/JP2006/304197

§ 371 Date: Jun. 11, 2007

(30) Foreign Application Priority Data
Feb. 28, 2005 (JP) 2005-053077

(51) Int. Cl. G01R 19/32

(52) U.S. Cl. 324/105

(57) ABSTRACT

An object of the present invention is to provide a fuel cell state monitor apparatus and method wherein detection errors can be reduced in a stable manner even when the ambient temperature fluctuates. The present invention includes temperature detection means for detecting the ambient temperature of fuel cells, state value detection means for detecting the state values indicating the specific state of the fuel cells, calibration value determination means for determining calibration values corresponding to the state values dependent on temperature on the basis of the detected ambient temperature, and correction means for correcting the state values on the basis of the determined calibration values. Standard calibration values stored in memory are appropriately compensated for temperature.

### TECHNICAL FIELD

The present invention relates to a fuel cell system, and particularly relates to the improvement of a cell voltage correction method for a fuel cell stack.

### BACKGROUND ART

In fuel cell systems mounted in electric automobiles and the like, the cells constituting the fuel cell stack used as the power source must generate electricity correctly. In conventional practice, monitor apparatuses for observing whether the cells are generating electricity properly have been developed.

For example, Japanese Patent Application Laid-Open No. 2003-243015 discloses a cell state monitor apparatus in which the wiring and circuit configuration are simplified by installing a local controller for each cell and sequentially transmitting state signals for the cells. The operating state of all the cells can be reliably determined if the voltage values of the channels for monitoring the state signals for the cells are correct.

However, when such monitor apparatuses are used, it is common to see non-uniformities developing between the channels of the monitor apparatus when the voltage for each cell is detected, and to encounter situations in which correction is needed to calibrate the voltages detected in the channels. Since the non-uniformities for each channel are unique to each channel, a calibration value corresponding to the characteristics of each separate channel must be read from memory and corrected for the voltage readouts. These calibration values are for use at normal room temperature.

However, as shown in FIG. 6, the voltage values detected at each channel are highly dependant on temperature, and the fluctuation in the voltage values detected at each channel becomes greater as the ambient temperature of the fuel cells deviates farther from room temperature. Therefore, although detection errors can be reduced by using the calibration values to accurately correct the voltage values when the ambient temperature is room temperature, the detection errors of the voltage values of the cells will no longer necessarily be small when the ambient temperature is not room temperature. In other words, at high or low ambient temperatures far from the standard temperature (room temperature 25° C.) at which the calibration values are determined, detection errors increase even if the calibration values are used, as shown in FIG. 6.

Particularly, fuel cells generate heat during an electrochemical reaction, and the ambient temperature widely fluctuates even in everyday environments. Therefore, the correct cell voltage values are often not corrected because the calibration values of the cell voltages at room temperature are used as is.

In view of this, an object of the present invention is to provide a fuel cell state monitor apparatus and method whereby detection errors can be reduced in a stable manner even when the ambient temperature fluctuates.

### DISCLOSURE OF INVENTION

In order to resolve these problems, the present invention is a fuel cell state monitor apparatus for monitoring a state of fuel cells on the basis of a state value indicating a specific state of the fuel cells, characterized in that a temperature-dependent state value is corrected based on a calibration value determined based on the ambient temperature of the fuel cells or the monitor apparatus.

Also, the present invention is a fuel cell state monitor apparatus comprising temperature detection means for detecting an ambient temperature of fuel cells or the monitor apparatus, state value detection means for detecting a state value indicating a specific state of the fuel cells, calibration value determination means for determining a calibration value corresponding to the temperature-dependent state value on the basis of the detected ambient temperature, and correction means for correcting the state value on the basis of the determined calibration value.

Furthermore, the present invention is a fuel cell state monitor apparatus comprising a temperature detecting sensor for detecting the ambient temperature of fuel cells or the monitor apparatus, a state value detecting sensor for detecting a state value indicating a specific state of the fuel cells, and a control apparatus for determining a calibration value corresponding to the temperature-dependent state value on the basis of the detected ambient temperature, and correcting the state value on the basis of the determined calibration value.

Furthermore, the present invention is a fuel cell state monitoring method comprising the steps of detecting the ambient temperature of fuel cells or the monitor apparatus, detecting a state value indicating a specific state of the fuel cells, determining a calibration value corresponding to the state value on the basis of the detected ambient temperature, and correcting the state value on the basis of the determined calibration value.

According to the present invention, even if the calibration value for correcting the state value is initially set at a specific temperature (for example, room temperature), the state value can no longer be corrected accurately with the calibration value when the ambient temperature of the fuel cells or the monitor apparatus deviates from this specific temperature if the state value is dependent on temperature. At this point, according to the present invention, the calibration value is determined in accordance with the ambient temperature, or, specifically, the calibration value is determined in accordance with the temperature characteristics of the state value. Therefore, the state value, which is determined by the channel of the monitor apparatus, can be corrected in the optimal manner even if the state value is dependent on temperature.

The term “specific state value” used herein refers to a physical value dependent on temperature pertaining to a fuel cell, and possible examples include voltage, electric power, electric current, pressure, and the like. If the state value is voltage value, the present invention includes temperature detection means for detecting the ambient temperature of the fuel cells or the monitor apparatus, voltage value detection means for detecting the voltage value of unit cells that constitute a fuel cell, calibration value determination means for determining a calibration value corresponding to the voltage value on the basis of the detected ambient temperature, and correction means for correcting the voltage value on the basis of the determined calibration value.

The present invention preferably includes memory for storing a standard calibration value that corresponds to the state value at a specific temperature, wherein compensated a calibration value is calculated by compensating the standard calibration value for temperature on the basis of the ambient temperature taking into account the temperature dependence of the state value, and the compensated calibration value is used to correct the state value instead of the standard calibration value. According to this configuration, detection errors in the voltage values can be minimized because the standard calibration values are compensated for temperature on the basis of the ambient temperature and are updated to compensated calibration value if the standard calibration value at a specific reference temperature (for example, room temperature) is stored in memory. The compensated calibration value, obtained by compensating the corrected calibration value for temperature, may be stored in memory as a new calibration value and the calibration value may be updated, but the calculated compensated calibration value may also be outputted in each case without being updated.

In the present invention, it is preferable that a determination is made as to whether or not the current state value is corrected, based on the difference between the ambient temperature at the time the previous state value is corrected and the currently detected ambient temperature. According to this configuration, when the ambient temperature of the fuel cells or the monitor apparatus is constantly fluctuating, the calibration value is compensated for temperature only when the degree of fluctuation is greater than a specific amount, for example. It is therefore possible to avoid needless operations of compensating the calibration value for temperature regardless of whether the change in the ambient temperature is small. In other words, it is possible to control the system so that the calibration value is compensated for temperature according to the present invention only when the ambient temperature has changed to an extent that substantially affects the system operation.

For example, in the present invention, the fuel cells are configured from a plurality of unit cells, and voltage values are corrected for each of the plurality of unit cells by using voltage values detected from the plurality of unit cells as the state values during startup of the fuel cell system. According to this configuration, since the ambient temperature is measured and the voltage values are corrected at startup, it is possible to output voltage values with small detection errors from the beginning of system startup.

### BRIEF DESCRIPTION OF DRAWINGS

FIG. 1 is a block diagram of a fuel cell system including the state monitor apparatus of the present invention;

FIG. 2 is a flowchart describing the process of compensating the calibration values for temperature in the fuel cell state monitoring method;

FIG. 3 is a flowchart describing the process of detecting abnormalities in the fuel cell state monitoring method;

FIG. 4 is an example of a memory map of the EEPROM in the present embodiment;

FIG. 5 is a diagram comparing the present invention with a conventional method of dealing with detection errors in the cell voltages; and

FIG. 6 is a temperature characteristic diagram of cell voltage detection errors when the voltage values are corrected and not corrected.

FIG. 7 is a functional block diagram of a fuel cell state monitor apparatus in the present invention.

### BEST MODE FOR CARRYING OUT THE INVENTION

Next, the preferred embodiments of working the present invention will be described with reference to the diagrams.

In the embodiments of the present invention, the state monitoring method of the present invention is applied to a fuel cell system mounted in an electric automobile as a moving vehicle.

In the following embodiments, the cells of a fuel cell stack and the channels of a monitor apparatus for detecting the voltages of the cells are described as having a one-to-one correspondence, but the system may also have channels for detecting voltage values for a plurality of cells, or channels for detecting voltage values for randomly sampled cells.

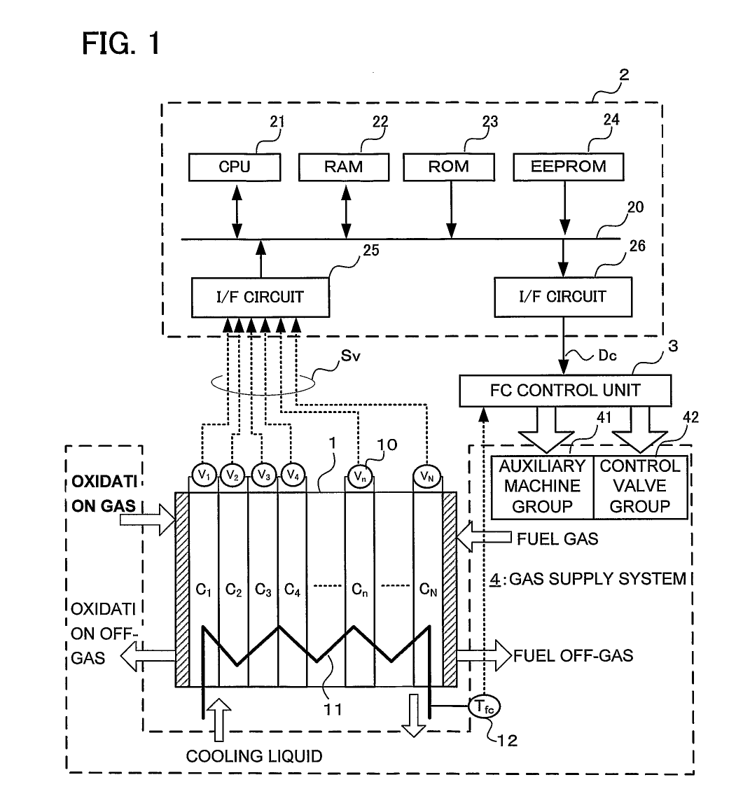

FIG. 1 is an entire depiction of a main fuel cell system 1. As shown in FIG. 1, the main fuel cell system is configured including a fuel cell stack 1, a fuel cell state monitor apparatus 2, a fuel cell control unit 3, and a gas supply system 4.

The fuel cell stack 1 is configured by layering (stacking) cells C₁-C_{N} (N is an arbitrary natural number) that each induce electromotive force and generate specific voltage values V₁-V_{N}. Each of the cells Cₙ (1≦n≦N) is configured with an MEA (Membrane Electrode Assembly) as a power generator held between a pair of separators provided with a hydrogen gas duct, an air duct, and a cooling liquid duct. Each MEA is structured with a polyelectrolyte film held between two electrodes, an anode and a cathode. The anodes are provided with an anode catalyst layer on top of a porous supporting layer, and the cathodes are provided with a cathode catalyst layer on top of a porous supporting layer. To cause an inverse reaction of water electrolysis in the fuel cells, hydrogen gas is supplied as fuel gas to the anode side, and air is supplied as oxidation gas to the cathode side. The reaction in formula (1) is caused on the anode side and the reaction in formula (2) is caused on the cathode side to generate electric current.
H₂→2H⁺+2e⁻ (1)
2H⁺+2e⁻+(½)O₂→H₂O (2)

When the vehicle is operated, constant cell voltage is generated between the anodes and cathodes by the electrochemical reactions corresponding to the above formulas in the cells Cₙ. Since the cells Cₙ are connected in series, a specific high pressure voltage (for example, about 500 V) is generated at the output terminals of the fuel cell stack 1.

Voltage sensors 10 detect the voltage values Vₙ (1≦n≦N) generated in the cells Cₙ as state values relating to the present invention, and supply these values as detection signals Sᵥ to the fuel cell state monitor apparatus 2.

A cooling liquid duct 11 extracts the heat from the electrochemical reactions in the fuel cell stack 1, diverts cooling liquid to the cells to cool the cells in the fuel cell stack, and then collects and discharges the cooling liquid from the cells. The cooling liquid duct 11 is cooled by a radiator (not shown), and is forcefully circulated by a cooling liquid pump.

The fuel cell stack 1 outlet of the cooling liquid duct 11 is provided with a temperature sensor 12 for detecting the ambient temperature in the present invention. Since the cooling liquid extracts and discharges the heat in the cells, the temperature of the cooling liquid near the outlet of the fuel cell stack 1 is virtually equal to the temperature of the cells. Therefore, the temperature detected by this temperature sensor 12 is equal to the ambient temperature of the fuel cell stack.

The gas supply system 4 is configured so as to supply hydrogen gas as fuel gas to the anode side of the cells of the fuel cell stack 1, to cause the reaction in formula (1), and to discharge the exhaust gas as fuel off-gas. The system also supplies air as oxidation gas to the cathode side of the cells of the fuel cell stack 1, causes the reaction in formula (2), and discharges the exhaust gas as oxidation off-gas.

Specifically, the gas supply system includes a hydrogen tank as a fuel gas source, various shut-off valves, a regulator valve, a gas-liquid separator, a hydrogen pump, and a purge shut-off valve on the side at which fuel gas is supplied. A compressor, a humidifier, or the like is also included on the side at which oxidation gas is supplied. The fuel off-gas is diluted by the oxidation off-gas so that the hydrogen gas concentration falls to below the oxidation level, and then the fuel off-gas is discharged.

In addition, the fuel cell system also includes a cooling system for circulating cooling liquid to cool the interior of the fuel cell stack 1, and an electric power system for charging the electricity generated by the fuel cell stack 1 and supplying a load.

The fuel cell state monitor apparatus 2 is configured as a computer apparatus, which includes an internal bus 20, CPU 21, RAM 22, ROM 23, EEPROM 24, an interfaces (I/F) circuits 25 and 26. The CPU 21 is the control apparatus relating to the present invention, and causes the main apparatus to implement the state monitoring method relating to the present invention by sequentially reading and executing control programs stored in the ROM 23. The RAM 22 is used as a storage area while the CPU 21 is operating, and the ROM 23 provides a storage area for the control programs relating to the state monitoring method of the present invention. The interface circuits 25 and 26 latch onto and electrically amplify the data supplied from the CPU 21 and supply the data in parallel or in serial to the exterior when the circuits function as output, and the circuits latch onto the data received from the exterior and output the data at a suitable timing to the internal bus 20 when the circuits function as input. The EEPROM (electrically erasable programmable read-only memory) 24 stores the resolution-correlated (accuracy-correlated) calibration values for the cell voltage values that are equivalent to the state values relating to the present invention. This EEPROM is ROM that is capable of electrically erasing (rewriting) data, and the data is not lost even if the power source is cut off. A greater voltage is required to erase data than to read data, but data can be erased and rewritten with the EEPROM still mounted on the substrate because the power source voltage is increased within the EEPROM.

The term “calibration value” as used herein refers to one or a plurality of value stored for each channel. These are values for correcting non-uniformities to the correct voltage values because non-uniformities occur in the voltage values outputted to each channel. Thus, the “calibration value are prepared and stored for each channel of the fuel cell, and may vary linearly with some offset corresponding to the input state (voltage) value. A series of the calibration value can be prepared and stored through measuring inputs and outputs of each channel. Originally, temperature sensors and the like for detecting the voltage of the cells in a fuel cell were all manufactured according to the same stipulations, and it was expected that the same voltage values were detected if the same gas was supplied. However, in practice, the temperature sensor yields large non-uniformities among channel, which results in non-uniformities in the detected voltage values even if the same amount of gas is supplied. Therefore, calibration values specified for each channel are used. The detected voltages can be corrected and the accuracy of the detected voltage values can be increased with a configuration in which the detected values of the cell voltages measured in each channel are inputted to the EEPROM 24, and calibration values for amending the detected values to the correct voltage values are read out. For example, in a channel corresponding to a certain cell Cx, +0.2 V is stored as the calibration value in response to a specific measured cell voltage (here 1.0 V) when there is a tendency for a cell voltage that is 0.2 V less than the actual electromotive force to be measured at room temperature. When the cell voltage value detected for the channel corresponding to this cell Cx is 1.0 V, then +0.2 V is calculated as the calibration value and 1.2 V is outputted as the corrected voltage value. Since the fuel cell stack includes sensors for several hundred channels, the calibration values for each channel are stored in the EEPROM 24.

The calibration values stored in the EEPROM 24 are initially those selected for each channel at a standard temperature, for example, room temperature. Generally, since the cell voltage values detected at each channel depend on the temperature, the calibration values are selected so as to minimize the errors in the cell voltage values at a standard temperature, for example, room temperature. The present invention is based on the standard calibration values at room temperature, but the standard calibration values are also revised based in accordance with ambient temperatures other than room temperature.

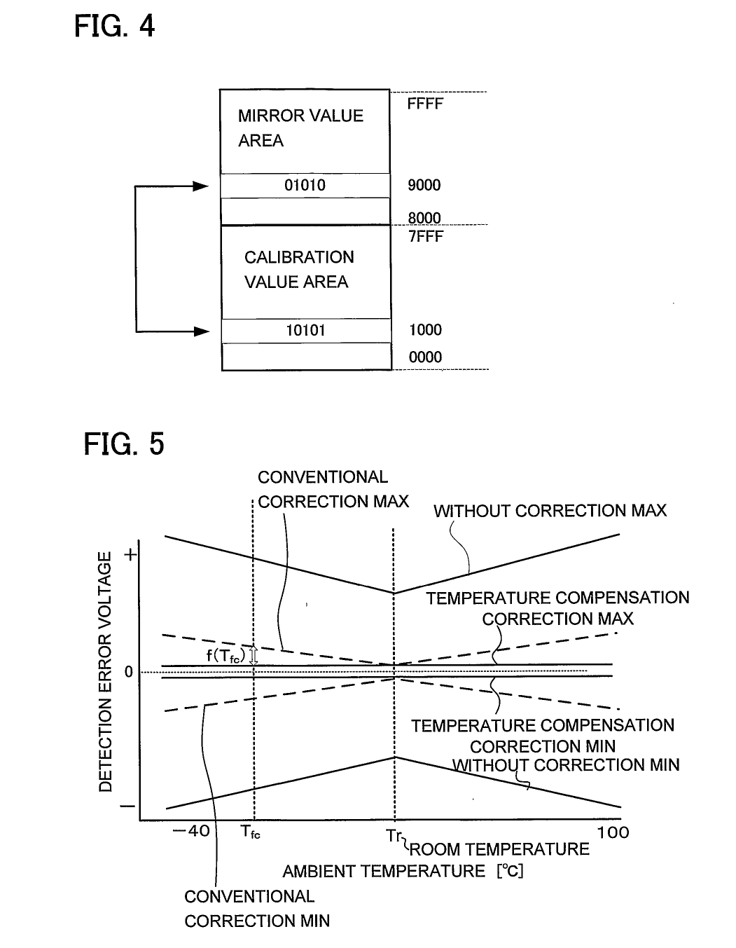

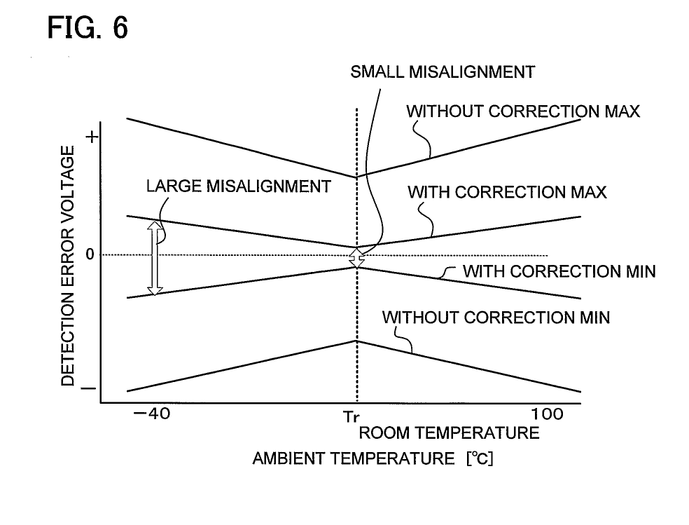

FIG. 4 shows a memory map of the EEPROM 24. FIG. 4 shows an example of storing calibration values in 64 KB of ROM, wherein the calibration values are stored in the lower 32 KB of a calibration value area from 0000H to 7FFFH, and the mirror values are stored in the upper 32 KB of a mirror value area from 8000H to FFFFH. The calibration values are divided and stored for each channel in the calibration value area and the mirror value area. The term “mirror value” refers to a value resulting from the bit inversion of a calibration value. The mirror values are stored in the mirror value area in the EEPROM 24 in accordance with the calibration values stored in the calibration value area. For example, the mirror value corresponding to the calibration value of a certain channel is stored at an address calculated by adding 8000H to the address where the calibration value is stored. In the memory map shown in FIG. 4, if the calibration value stored at 1000H is 10101B, then the mirror value 01010B, which is the bit-inverted value, is stored at 9000H. The mirror values are provided for the purpose of a mirror check.

The term “mirror check” refers to a process of determining whether the calibration values read from the EEPROM are correct. The fuel cell system is subject to bit errors and the like when data is read from the EEPROM or another such memory device in an environment subjected to high-temperature, high-humidity, static electricity or electromagnetic waves. A mirror check is performed because the fuel cell system cannot be controlled based on irregular values resulting from such bit errors. The mirror values are the redundant data of the calibration values, and when a specific calibration value is acquired according to a certain cell voltage value, the CPU 21 is used to read the calibration value and the corresponding mirror value from the EEPROM 24, and to determine whether they have the correct bit-inverted relationship. Although low, the possibility of bit errors occurring in the data read from any address does have a constant ratio, but the probability of the same bit error occurring when calibration values and mirror values stored at different addresses are read is extremely low, and it may be assumed that this will not actually occur. Therefore, aberrant values resulting from memory read errors can be excluded if the values are treated differently as though a bit error has occurred. This is true only in cases in which the calibration value and the mirror value do not have a bit-inverted relationship. There are various other possibilities besides the mirror check for determining the accuracy with which data is read from the EEPROM, and the method used is not particularly limited.

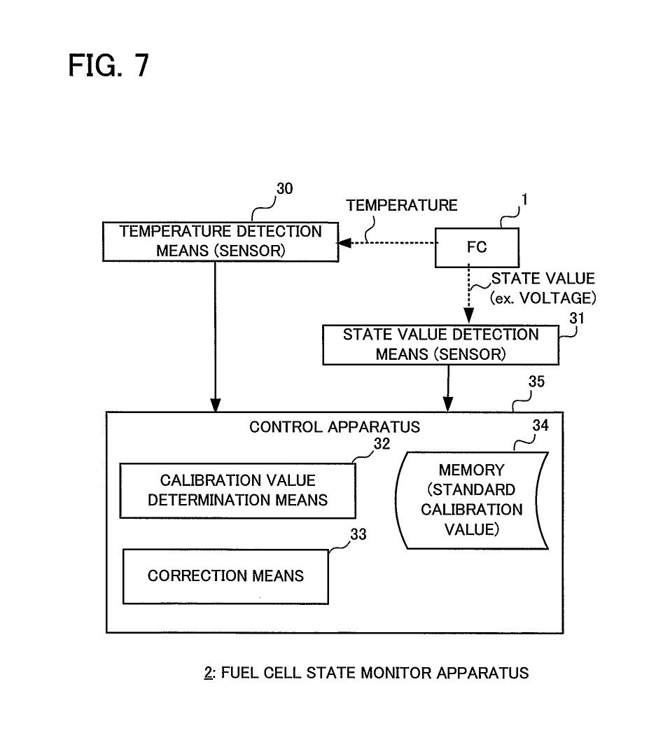

FIG. 7 shows a functional block diagram that is implemented by the fuel cell state monitor apparatus 2. The fuel cell state monitor apparatus 2 functionally comprises: temperature detection means (sensor) 30 for detecting an ambient temperature T_{fc} of fuel cells 1 or the monitor apparatus 2; state value detection means (sensor) 31 for detecting a state value indicating a specific state of the fuel cells 1; calibration value determination means 32 for determining a calibration value corresponding to the temperature-dependent state value on the basis of the detected ambient temperature T_{fc}; and correction means 33 for correcting the state values on the basis of the determined calibration value. The calibration value determination means 32 and the correction means 33 are included in control apparatus 35 for determining a calibration value corresponding to the temperature-dependent state value on the basis of the detected ambient temperature, and correcting the state value on the basis of the determined calibration value. The control apparatus 35 includes memory 34 for storing a standard calibration value that corresponds to the state value at a specific temperature,

The fuel cell control unit 3 is a computer apparatus that operates independent of the fuel cell state monitor apparatus 2 and performs the necessary controls on the system in accordance with the correction values Dc for the corrected cell voltage values inputted by the fuel cell state monitor apparatus 2. For example, the fuel cell control unit 3 controls the operation of an auxiliary machine group 41 that includes the compressor and the monitor of the gas supply system 4, and also controls the opening and closing of a control valve group 42 for controlling the flow of gas through the fuel gas system and the oxidation gas system. The control method is based on the control methods of conventional fuel cell systems. For example, the operation of the fuel cell stack 1 is continued in an optimal manner by controlling the auxiliary machine group 41 and the control valve group 42 according to the cell voltages indicated by the correction values Dc of the cell voltages.

Other possible examples of the control system include an electric power control unit and a motion control unit (not shown). The electric power control unit manages the generation of electricity by the fuel cell stack 1 and the charging of a secondary battery with regenerative electric power. The motion control unit controls the driving of a motor that uses generated electric power provided by the control operation of the fuel cell control unit 3.

Next, the fuel cell state monitoring method of the present invention will be described.

In order to alleviate the effects of the nonuniformities in each cell, in the present embodiment, the cell voltage values Vₙ measured in each channel of the fuel cell stack 1 are configured so that the differences between the detection errors and the accurate voltage values are reduced by reading and applying the calibration values for the detected cell voltages from the EEPROM 24. In other words, the cell voltage values Vₙ are corrected on the basis of the calibration values determined based on the ambient temperature T_{fc} of the fuel cell stack 1. Specifically, the fuel cell state monitor apparatus 2 reads the calibration values corresponding to the voltage values Vₙ detected by a voltage sensor 10 from the EEPROM 24, the calibration values are compensated for temperature on the basis of the ambient temperature T_{fc} detected by the temperature sensor 12 for detecting the ambient temperature of the fuel cell stack 1, and the calibration values compensated for temperature are outputted as the corrected cell voltage values Vₙ.

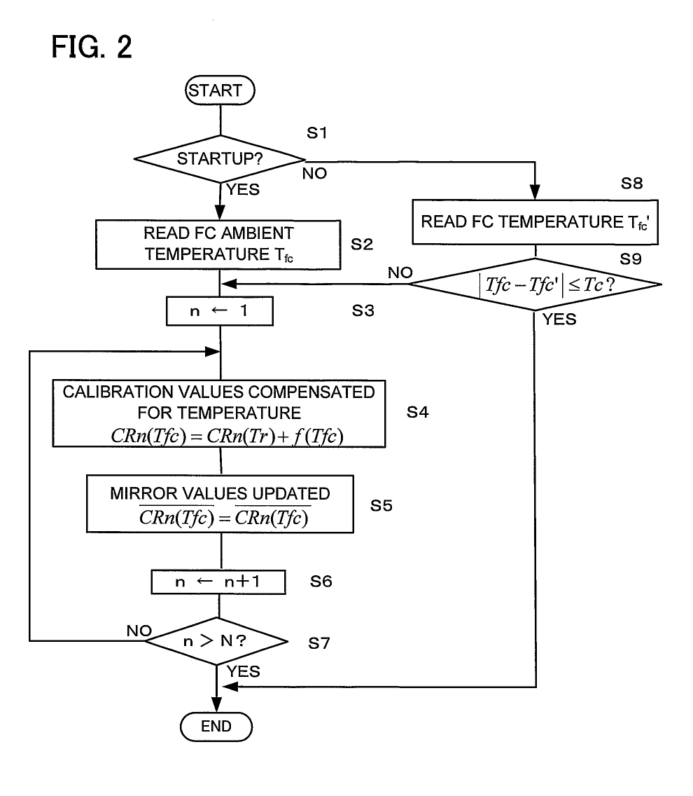

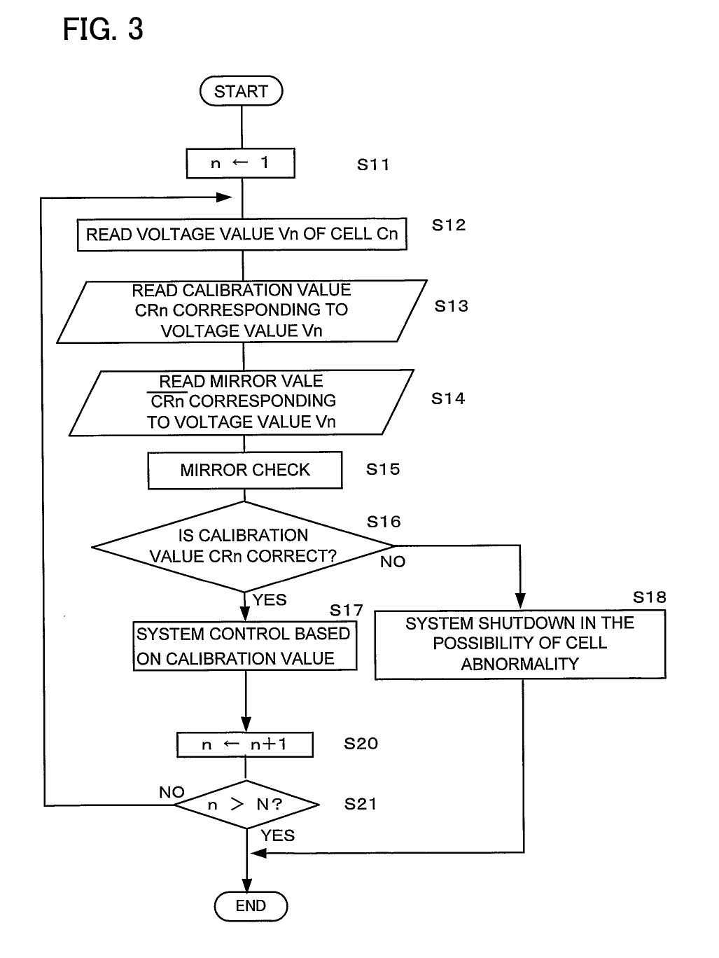

The specific operation of the present embodiment is described hereinbelow on the basis of the flowcharts in FIGS. 2 and 3. The flowchart in FIG. 2 stipulates the timing with which the compensation for temperature relating to the present invention is made. When the vehicle is started, the standard calibration values determined at room temperature for all the cells are updated with the calibration values compensated for temperature on the basis of the temperature at startup, and when the vehicle is in motion, the calibration values are updated in the same manner if a certain temperature change is occurred. The process in this flowchart is executed periodically.

A vehicle ignition IG signal inputted by the driver turning the key is referenced, and a determination is made as to whether the vehicle is being started (S1). During startup, or, specifically, when it is determined that the fuel cell system has just begun operating (S1: YES), a detection signal from the temperature sensor 12 is inputted to the fuel cell control unit 3, and the ambient temperature T_{fc} at startup is inputted to the fuel cell state monitor apparatus 2 (S2). Since the standard calibration values of the cell voltage values determined at room temperature are stored in the EEPROM 24, the standard calibration values are subsequently compensated for temperature on the basis of the ambient temperature T_{fc} and with reference to the temperature dependence of the cell voltage values Vₙ detected at each channel.

A counter n for specifying the cell number is set to “1” (S3), and the calibration values are compensated for temperature sequentially from the cell having a cell number 1 (S4). Specifically, the amount of fluctuation (T_{fc}) at the ambient temperature T_{fc} is added to the standard calibration values CRₙ (Tr) determined at room temperature Tr to calculate the calibration values CRₙ (T_{fc}) that have been compensated for temperature, and these values are updated as the calibration values that are to be referred to at this ambient temperature T_{fc}.

As shown in FIG. 5, the standard calibration values CRₙ (Tr) measured and determined at room temperature Tr exhibit temperature-dependent linear misalignment, as shown by the dotted lines. In this case, the maximum amount of fluctuation f (T_{fc}) from the calibration values at room temperature Tr is expressed by |k(T_{fc}−Tr)|, where k is the slope of the maximum amount of fluctuation. Therefore, the temperature-compensated calibration values CRₙ (T_{fc}) are expressed by:
CRₙ(T_{fc})=CRₙ(Tr)±f(T_{fc})(=|k(T_{fc}−Tr)|).
The maximum amount of fluctuation is added or subtracted depending on whether the calibration values are positive or negative. The compensated calibration values CRₙ (T_{fc}) may either be written over the standard calibration values in the EEPROM 24, or they may be stored in another area in the EEPROM. They may also be stored separately in the RAM 22.

When the calibration values CRₙ (T_{fc}) compensated for temperature have been calculated, the corresponding mirror values CRₙ (T_{fc}) are also calculated and are stored in specific areas corresponding to the compensated calibration values (S5). Specifically, the bit inversions of these calculated compensated calibration values CRₙ (T_{fc}) are calculated as the mirror values.

With the update of the standard calibration value for the n^{th} channel complete, the cell counter n increases by one (S6). As long as the cell counter n does not exceed the maximum cell number N (S7: NO), the temperature compensation of a calibration value for a new cell is repeated (S4-S6). When the cell counter n reaches the maximum channel number N (S7: YES), the calibration value update is complete.

Since the optimum calibration values corresponding to the ambient temperature T_{fc} at startup are obtained, the cell voltage values Vₙ detected by the voltage sensor 10 are corrected according to the temperature-compensated calibration values CRₙ (T_{fc}) that use these cell voltage values as minimum detection errors, and the corrected cell voltage values with the smallest errors are outputted.

The flowchart in FIG. 2 is executed periodically while the vehicle is in motion after startup. Since the vehicle is not going through startup while it is in motion (S1: NO), step S8 is executed. A new ambient temperature T_{fc}′ detected by the temperature sensor 12 is inputted via the fuel cell control unit 3 (S8). The (previous) ambient temperature T_{fc} during startup and the new ambient temperature T_{fc}′ are then compared, and an inspection is made as to whether the difference |T_{fc}−T_{fc}′| between the two is greater than a specific amount Tc (S9). If the difference between the previous and current ambient temperatures is equal to or less than Tc (S9: YES), then the temperature of the fuel cell stack 1 has not changed by much, which means that it is possible to accurately detect the voltages if the previous calibration values CRₙ (T_{fc}) compensated for temperature are used, and a new temperature compensation is therefore not performed. However, if the difference between the previous and current ambient temperatures is greater than Tc (S9: NO), it means that the temperature of the fuel cell stack 1 has greatly changed. In view of this, the new compensated calibration values CRₙ (T_{fc}′) and their mirror values /CRₙ (T_{fc}′) are updated for all of the cells in (S3-S7) in order to compensate the calibration values for temperature at the new ambient temperature T_{fc}′. The calibration values are updated to their optimum values according to the ambient temperature in these processes.

FIG. 3 shows the process of correcting voltage values and determining abnormalities for the cell voltage values Vₙ based on the calibration values CRₙ (T_{fc}) compensated for temperature. The flowchart in FIG. 3 is executed in cases in which the movement conditions have changed or the temperature conditions have greatly changed, including system startup.

First, a counter n for specifying one channel from multiple channels in the fuel cell stack 1 is set to 1 (S11). Next, a cell voltage value Vₙ is read from the voltage sensor provided to an n^{th} cell Cn (S12). This cell voltage value Vₙ is acquired via the interface circuit 25 by converting a detection signal Sv from analog to digital as needed. The signal is equivalent to the cell voltage value detected by the voltage sensor provided to the cell Cₙ. Next, the compensated calibration value CRₙ (T_{fc}) corresponding to this cell is read (S13). This calibration value is read from a specific area in the EEPROM when the calibration values are sequentially rewritten in the EEPROM 24 according to the ambient temperature T_{fc}, and is read from the equivalent area in the RAM when the compensated calibration values are stored separately in the RAM 22. The mirror value /CRₙ (T_{fc}) corresponding to the calibration value is read in the same manner (S14).

Next, a mirror check is performed (S15). The mirror check is used to determine whether the calibration value CRₙ (T_{fc}) and the mirror value /CRₙ (T_{fc}) have the correct bit-inverted relationship. The method for the mirror check is not limited, but, for example, a bit logic check is performed to determine whether the calibration value and the mirror value add up to a total bit value of “1”. When the relationship between the calibration value and the mirror value is not an accurate bit inversion, it is believed that a bit error has occurred in either the calibration value CRₙ (T_{fc}) or the mirror value /CRₙ (T_{fc}), in which case it is possible to determine that the calibration value CRₙ (T_{fc}) is abnormal.

When the result of this determination is that the calibration value CRₙ (T_{fc}) is abnormal (S16: YES), the cell voltage value Vₙ is corrected based on this calibration value CRₙ (T_{fc}), and the resulting value is transmitted to the fuel cell control unit as a voltage value whose detection error has been corrected (S17). When it is determined that the calibration value CRₙ (T_{fc}) is abnormal (S16: NO), the entire system is shut down for safety purposes (S18).

When this voltage correction is complete, the counter n is increased by one (S20). As long as the counter n does not exceed the cell number N (S21: NO), the process from reading to correcting the cell voltage value V is performed for the channel corresponding to the next cell Cₙ (the cell one number greater than the previous cell) (S12-S20). When the counter n exceeds N (S21: YES), the process is ended.

As described above, according to the present embodiment, accurate cell voltage values can be outputted regardless of whether the cell voltage values depend on temperature. This is because calibration values are determined in accordance with the ambient temperature when the ambient temperature T_{fc} of the fuel cell stack 1 is equal to or greater than room temperature, even if the calibration values for each channel are set for a specific temperature (for example, room temperature).

Also, according to the present embodiment, it is determined whether the current state value will be corrected based on the difference between the previous ambient temperature T_{fc} and the currently detected ambient temperature T_{fc}′. Therefore, the ambient temperature of the fuel cell stack 1 may be constantly fluctuating, but the calibration values are compensated for temperature only when the amount of fluctuation is greater than a specified amount Tc. It is therefore possible to avoid needless operations of compensating the calibration values for temperature regardless of whether the change in the ambient temperature is small.

In the above embodiment, the state of the fuel cells can be appropriately monitored at startup and at other times, because the fuel cell system is mounted in an electric automobile and is utilized according to the operating conditions of the electric automobile, including at least startup.

Also, in the above embodiment, bit errors can be accurately detected and abnormal values can be reliably determined, because the calibration values are determined by a mirror check, or, specifically, by drawing a comparison between the calibration values that correspond to the read state values and the inspected values (mirror values) of the calibration values that correspond to the state values.

### OTHER EMBODIMENTS

The present invention can be applied with various modifications made to the embodiment above.

For example, in the embodiment above, the temperature compensation of the calibration values involved adding and subtracting the amount of fluctuation from the standard calibration values, but the present invention is not limited to this option alone, and the temperature compensation method can be modified according to the temperature dependence of the state values as control objects.

Also, in the embodiment above, the temperature of the cooling liquid outlet of the fuel cell stack 1 is referred to as the ambient temperature, but reference may of course be made to another temperature. For example, the temperature around the monitor apparatus other than the fuel cell stack can be referred to as the ambient temperature.

Also, in the embodiment above, the calibration values were compensated for temperature for all the channels of all the cells during startup, but the present invention is not limited to this option alone. For example, the ambient temperature of the fuel cell system may be stored and recorded during system shutdown as well, and the voltage values detected at each channel may be compensated for temperature when it is determined that the ambient temperature at startup has changed since the previous shutdown, and the difference in the ambient temperature is greater than a specified amount.

For example, in the embodiment above, the fuel cell state monitor apparatus was applied to an electric automobile, but the present invention is not limited to this option alone, and may be applied to other vehicles, for example, boats and aircraft. The operational effects of being able to reduce the detection errors of the state values can be achieved with any ambient temperature.

### INDUSTRIAL APPLICABILITY

According to the present invention, the temperature-dependent state value is corrected based on the calibration value determined based on the ambient temperature of the fuel cells or the monitor apparatus. Specifically, even if the calibration value is set only for a specific temperature, the calibration value is determined again in accordance with the ambient temperature when the ambient temperature of the fuel cells or the monitor apparatus deviates from the specific temperature, and therefore the state value can always be corrected in the optimal manner even if the state value is dependent on temperature.

1.-2. (canceled)

3. A fuel cell state monitor apparatus comprising:
a temperature detecting sensor for detecting an ambient temperature of fuel cells or the monitor apparatus;
a state value detecting sensor for detecting a voltage value indicating a specific state of the fuel cells; and
a control apparatus for determining a calibration value corresponding to the temperature-dependent voltage value on the basis of the detected ambient temperature, and correcting the voltage value on the basis of the determined calibration value.

4. The fuel cell state monitor apparatus according to claim 3, comprising:
a memory for storing a standard calibration value that corresponds to the voltage value at a specific temperature,
wherein a compensated calibration value is calculated by compensating a standard calibration value for temperature on the basis of the ambient temperature taking into account temperature dependence of the voltage value, and the compensated calibration value is used to correct the voltage value instead of the standard calibration value.

5. The fuel cell state monitor apparatus according to claim 3,
wherein a determination is made as to whether or not a current voltage value is corrected, based on the difference between an ambient temperature at the time the previous voltage value is corrected and a currently detected ambient temperature.

6. The fuel cell state monitor apparatus according to claim 3,
wherein the fuel cells are configured from a plurality of unit cells; and
the voltage values are corrected for each of the plurality of unit cells using voltage values detected from the plurality of unit cells during startup of the fuel cell system.

7.-8. (canceled)

9. The fuel cell state monitor apparatus according to claim 4,
wherein a determination is made as to whether or not a current voltage value is corrected, based on the difference between an ambient temperature at the time the previous voltage value is corrected and a currently detected ambient temperature.

10. The fuel cell state monitor apparatus according to claim 4,
wherein the fuel cells are configured from a plurality of unit cells; and
the voltage values are corrected for each of the plurality of unit cells using voltage values detected from the plurality of unit cells during startup of the fuel cell system.
